(19) United States
(12) Patent Application Publication
(10) Pub. No.: US 2019/0271721 A1
(43) Pub. Date: Sep. 5, 2019

(54) SELF ALIGNED SORT PROBE CARD FOR SI BRIDGE WAFER

(71) Applicants: Dae-Woo KIM, Phoenix, AZ (US); Sujit SHARAN, Chandler, AZ (US)

(72) Inventors: Dae-Woo KIM, Phoenix, AZ (US); Sujit SHARAN, Chandler, AZ (US)

(21) Appl. No.: 16/322,430

(22) PCT Filed: Sep. 30, 2016
(86) PCT No.: PCT/US2016/054712

§ 371 Date: Jan. 31, 2019

(51) Int. Cl. G01R 1/073; G01R 31/26; G01R 31/28

(52) U.S. Cl. CPC G01R 1/07307; G01R 31/2886; G01R 31/2601

(57) ABSTRACT

Apparatus and methods for adjusting probes of a integrated circuit tester are provided. In an examples, an apparatus can include an array of probes having a nominal pitch, a space transformer configured to provide electrical connections from a plurality of terminals of the space transformer to the plurality of probes, wherein a second nominal pitch of the plurality of terminals is different than the nominal pitch of the probes, and a thermal device configured to adjust a nominal spacing of the array of probes using heat transfer.

### TECHNICAL FIELD

The disclosure herein relates generally probe head assemblies for testing integrated electronic circuits and more particularly to adjustable probe head assemblies.

### BACKGROUND

The trend in electronic device production, particularly in integrated circuit technology, has been toward fabricating increasingly larger numbers of discrete circuit elements with higher operating frequencies and smaller circuit element geometries on a single device substrate. After these devices are fabricated, they may be subject to various tests to verify functionality, quantify operating characteristics, and/or characterize the manufacturing process.

Traditionally, these electrical tests have been performed by forming a plurality of electrical contacts with a device under test (DUT), providing electric current to the DUT in the form of input, or test, signals, and receiving electric current or other outputs from the DUT in the form of output, or resultant, signals. The response of the DUT to various input signals and/or power levels may then be quantified through analysis of the input and/or output signals.

However, as a density of the individual circuit elements increases, a density and/or number of bond and/or contact pads, which may be contacted to perform the electrical testing, also may increase. Also, a pitch and/or spacing between adjacent pads may decrease and/or a size of the individual pads may decrease.

This evolution of integrated circuit technology presents unique challenges to the manufacturers of test systems that may be utilized to perform electrical tests. Thus, there exists a need for improved probe head assemblies, probe head assembly components, and methods of operation thereof.

### BRIEF DESCRIPTION OF THE DRAWINGS

In the drawings, which are not necessarily drawn to scale, like numerals may describe similar components in different views. Like numerals having different letter suffixes may represent different instances of similar components. Sonic embodiments are illustrated by way of example, and not limitation, in the figures of the accompanying drawings in which:

FIG. 1 illustrates generally a portion of test probe assembly 100 according to an example of the present subject matter.

FIG. 2 illustrates generally a flowchart of a method 200 of using a temperature adjustable probe card according to various examples of the present subject matter.

FIG. 3 illustrates a system level diagram, according to one embodiment of the present subject matter.

### DETAILED DESCRIPTION

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

New technology has evolved for dense multiple-chip packages that accommodates interconnections between chips using a very thin silicon bridge. The terminals of the chips and the corresponding bridge can have a pitch spacing of about 65 micrometers (um) or less to enable extremely high density of inputs and outputs of the package.

Each bridge, even for the same interface type, may need a slightly different test equipment for spacing variations that can result from package die embedding process, chip attach process, and package layer count which can impact package bump compensation factor and Si bridge shrink factor. Even small adjustments in pitch based on the above factors, can require a different test probe assembly which, at present, can cost $500,000 each. The present inventors have recognized that thermal control of a portion of a test probe assembly can alleviate acquiring a different test probe assembly for each variation of pitch of a device under test. For example, a test probe assembly with a heater attachment can allow the assembly to be physically adjusted over a range of different pitch dimensions. In an example, probes having a first nominal pitch or spacing can be adjusted by transferring heat to a portion of the test probe assembly or transferring heat from the test probe assembly. Although not limited as such, transferring heat to the test probe assembly can cause expansion and an increase in pitch or spacing of the probes. In some examples, transferring heat from the test probe assembly can decrease the pitch or spacing of the probes.

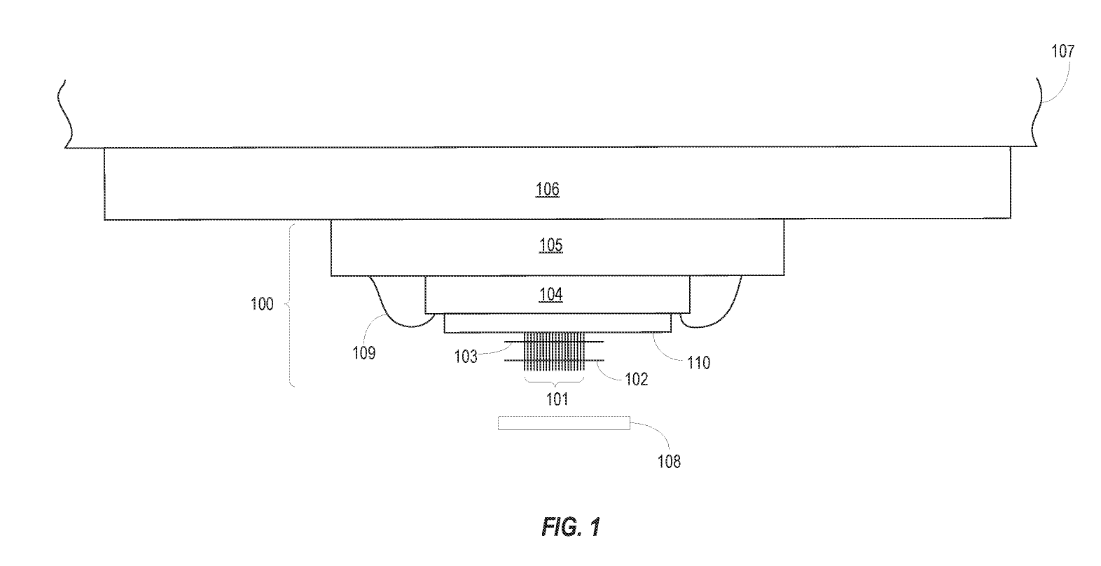

FIG. 1 illustrates generally a portion of test probe assembly 100 according to an example of the present subject matter. In certain examples, the test probe assembly 100 can include a plurality of probes 101, one or more guide plates 102, 103, a space transformer 104, and one or more printed circuit boards (PCBs) 105, 106. In certain examples, the combination of the space transformer 104 and the PCBs 105, 106 can route signals between the test equipment 107 and the DUT 108. In an example, a first PCB 106 can provide electrical connectors for the test equipment. A second PCB 105, sometimes referred to as a mini-PCB can route signals from the space transformer 104 to the first PCB 106. In certain examples, the mini-PCB 105 can provide wire bond pads to electrically couple the mini-PCB 105 with the space transformer 104.

In certain examples, the guide plates 102, 103 are optional. The guide plates 102, 103 can include openings that allow the probes 101 to pass through. In certain examples, the guide plates 102, 103 can hold the probes 101 in formation for interfacing to a DUT 108. In certain examples, the spacing of the openings in the guide plates, 102, 103, can determine the spacing or pitch of the probes 101.

In certain examples, the space transformer 104 can include an electrical trace connected to each probe 101. The plurality of electrical traces of the space transformer 104 can be routed to a corresponding wire bond pad. In certain examples, the wire bond pads can be arranged with a different pitch than the pitch of the probes 101 thus transforming the space between individual input/output (I/O) points of the DUT 108. In certain examples, a wire bond 109 can electrically couple the wire bond pads of the space transformer 104 to the second PCB 105 that routes the signals for connection to test equipment. In some examples, the space transformer 104 can include any suitable structure that is configured to receive the plurality of test signals and to transform the spacing of the plurality of test signals from a first pitch, or average spacing, on a first surface of the space transformer 104 to a second (different) pitch, or average spacing, on a second surface of the space transformer 104 that is generally opposed to the first surface of the space transformer 104. In certain examples, the plurality of probes 101 can be arranged with a nominal pitch that is matched to the terminations of the DUT 108, such as a silicon bridge. The plurality of probes 101 can be electrically connected to the space transformer 104.

In certain examples, the test probe assembly 100 can include a thermal device 110. In some examples, the thermal device 110 can be used to add heat to the space transformer 104, the probes 101, the first guide plate 102, the second guide plate, or a combination thereof, and to adjust the nominal spacing of the probes 101. In some examples, the thermal device 110 can be used to remove heat from the space transformer 104, the probes 101, the first guide plate 102, the second guide plate 103, or a combinations thereof, to adjust the nominal spacing of the probes 101. In certain examples, the thermal device 110 can he used to either add heat to, or to remove heat from, the space transformer 104, the probes 101, the first guide plate 102, the second guide plate 103, or a combinations thereof, to adjust the nominal spacing of the probes 101.

In some examples, the thermal device 110 can be mounted to the space transformer 104. In some examples, the thermal device 110 can be mounted to the probes 101. In sonic examples, the thermal device 110 can be mounted to one or both of the guide plates 102, 103.

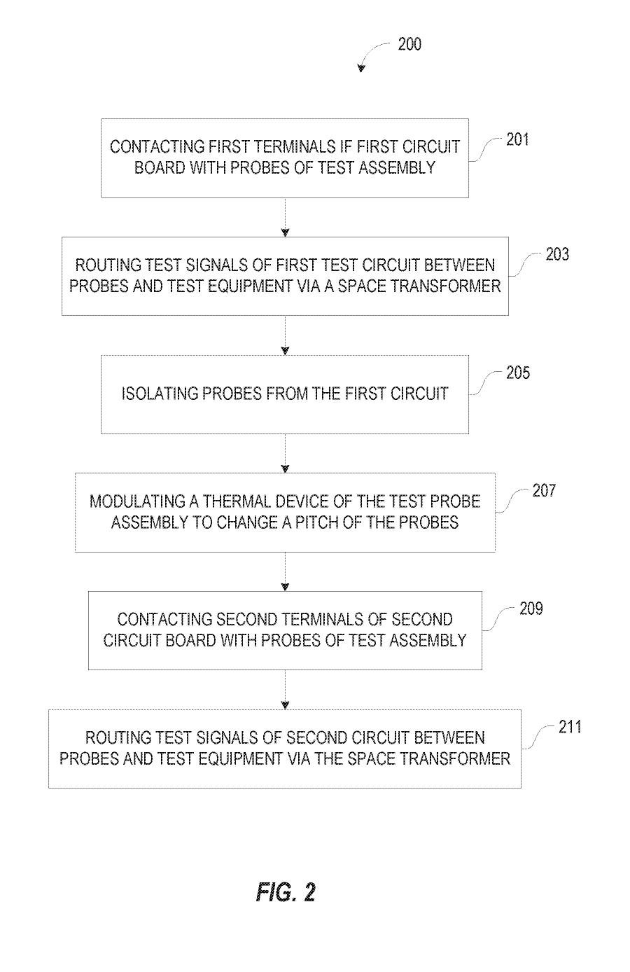

FIG. 2 illustrates generally a flowchart of a method 200 of using a temperature adjustable probe card according to various examples of the present subject matter. At 201, an array of test probes of the temperature adjustable probe card can contact a first plurality of terminals of a first circuit. In certain examples, a pitch of the array of test probes and the first plurality of terminal scan be on the order of 65 um or less. In some examples, the first circuit is a silicon bridge wafer. At 203, test signals for the first circuit can be routed between the array of test probes and test equipment via a space transformer coupled to the array of test probes. At 205, at the conclusion of testing the first circuit, the first circuit can be electrically and mechanically isolated from the first plurality of terminals. At 207, a thermal device can be modulated to change a nominal pitch of the array of test probes. In certain examples, the thermal device can include a heater. In some examples, the thermal device can include a cooling apparatus such as a refrigeration system or a cooling apparatus. In certain examples, the thermal device can include a heater and a cooling apparatus. At 209, the array of test probes of the temperature adjustable probe card can contact a second plurality of terminals of a second circuit. In certain examples, a pitch of the second plurality of terminals is different than the pitch of the first plurality of terminals. In some examples, the second circuit is a silicon bridge wafer. At 211, test signals for the second circuit can be routed between the array of test probes and test equipment via a space transformer coupled to the array of test probes. In some examples, the space transformer can be configured with materials that have a predictable expansion and contraction characteristics with respect to temperature. In certain examples, the space transformers can be constructed to have differing temperature-related expansion and contraction characteristic with respect to the contact plane of the probes, such that for a particular temperature change of the ambient about the space transformer, the change in pitch of the probes in a first direction is predictably different than the change in pitch of the probes in a second direction.

In certain examples, the difference between the nominal pitch of first plurality of terminals and the nominal pitch of the second plurality of terminals is such that the array of test probes can not accommodate test connections with the terminals of both circuits without physical adjustment of the pitch of the test probes. In certain examples, the pitch of the test probes can be adjusted by heating or cooling the space transformer, one or more of the guide plates, the probes or a combination thereof.

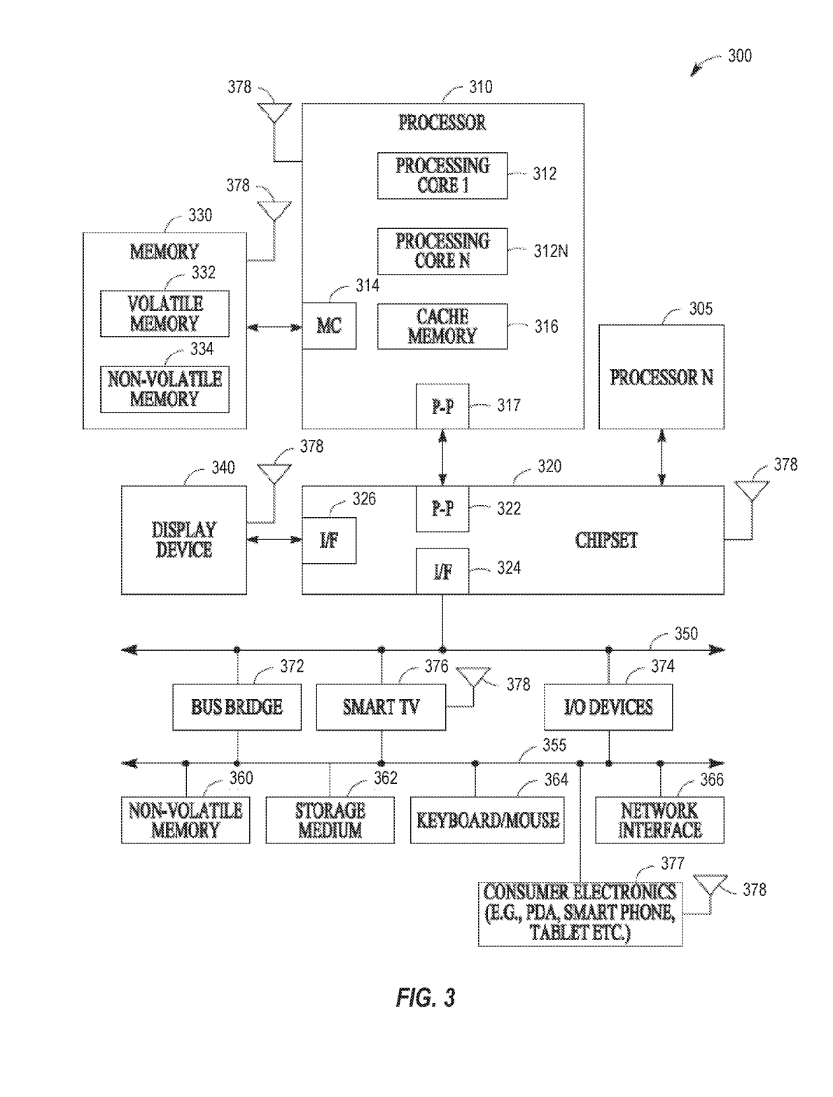

FIG. 3 illustrates a system level diagram, according to one embodiment of the subject matter. For instance, FIG. 3 depicts an example of a system 300 that can include the test probe assembly as discussed above. FIG. 3 is included to show an example of a higher level system for the present subject matter. In one embodiment, system 300 includes, but is not limited to, a desktop computer, a laptop computer, a netbook, a tablet, a notebook computer, a personal digital assistant (PDA), a server, a workstation, a cellular telephone, a mobile computing device, a smart phone, an Internet appliance or any other type of computing device that can control the test probe assembly as discussed above. In some embodiments, system 300 is a system on a chip (SOC) system.

In one embodiment, processor 310 has one or more processing cores 312 and 312N, where 312N represents the Nth processor core inside processor 310 where N is a positive integer. In one embodiment, system 300 includes multiple processors including 310 and 305, where processor 305 has logic similar or identical to the logic of processor 310. In some embodiments, processing core 312 includes, but is not limited to, pre-fetch logic to fetch instructions, decode logic to decode the instructions, execution logic to execute instructions and the like. In some embodiments, processor 310 has a cache memory 316 to cache instructions and/or data for system 300. Cache memory 316 may be organized into a hierarchal structure including one or more levels of cache memory.

In some embodiments, processor 310 includes a memory controller 314, which is operable to perform functions that enable the processor 310 to access and communicate with memory 330 that includes a volatile memory 332 and/or a non-volatile memory 334. In some embodiments, processor 310 is coupled with memory 330 and chipset 320. Processor 310 may also be coupled to a wireless antenna 378 to communicate with any device configured to transmit and/or receive wireless signals. In one embodiment, the wireless antenna interface 378 operates in accordance with, but is not limited to, the IEEE 802.11 standard and its related family, Home Plug AV (HPAV), Ultra Wide Band (UVB), Bluetooth, WiMax, or any form of wireless communication protocol.

In some embodiments, volatile memory 332 includes, but is not limited to, Synchronous Dynamic Random Access Memory (SDRAM), Dynamic Random Access Memory (DRAM), RAMBUS Dynamic Random Access Memory (RDRAM), and/or any other type of random access memory device. Non-volatile memory 334 includes, but is not limited to, flash memory, phase change memory (PCM), read-only memory (ROM), electrically erasable programmable read-only memory (EEPROM), or any other type of non-volatile memory device.

Memory 330 stores information and instructions to be executed by processor 310. In one embodiment, memory 330 may also store temporary variables or other intermediate information while processor 310 is executing instructions. In the illustrated embodiment, chipset 320 connects with processor 310 via Point-to-Point (PtP or P-P) interfaces 317 and 322. Chipset 320 enables processor 310 to connect to other elements in system 300. In some embodiments of the invention, interfaces 317 and 322 operate in accordance with a PtP communication protocol such as the Intel® QuickPath Interconnect (QPI) or the like. In other embodiments, a different interconnect may be used.

In some embodiments, chipset 320 is operable to communicate with processor 310, 305N, display device 340, and other devices 372, 376, 374, 360, 362, 364, 366, 377, etc. Chipset 320 may also be coupled to a wireless antenna 378 to communicate with any device configured to transmit and/or receive wireless signals.

Chipset 320 connects to display device 340 via interface 326. Display 340 may be, for example, a liquid crystal display (LCD), a plasma display, cathode ray tube (CRT) display, or any other form of visual display device. In some embodiments of the invention, processor 310 and chipset 320 are merged into a single SOC. In addition, chipset 320 connects to one or more buses 350 and 355 that interconnect various elements 374, 360, 362, 364, and 366. Buses 350 and 355 may be interconnected together via a bus bridge 372.

In one embodiment, chipset 320 couples with a non-volatile memory 360, a mass storage device(s) 362, a keyboard/mouse 364, and a network interface 366 via interface 324 and/or 304, smart IV 376, consumer electronics 377, etc.

In one embodiment, mass storage device 362 includes, but is not limited to, a solid state drive, a hard disk drive, a universal serial bus flash memory drive, or any other form of computer data storage medium. In one embodiment, network interface 366 is implemented by any type of well known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 802.11 standard and its related family, Home Plug AV (HPAV), Ultra Wide Band (UWB), Bluetooth, WiMax, or any form of wireless communication protocol.

While the modules shown in FIG. 3 are depicted as separate blocks within the system 300, the functions performed by some of these blocks may be integrated within a single semiconductor circuit or may be implemented using two or more separate integrated circuits. For example, although cache memory 316 is depicted as a separate block within processor 310, cache memory 316 (or selected aspects of 316) can be incorporated into processor core 312.

### ADDITIONAL EXAMPLES AND NOTES

In Example 1, an apparatus for testing silicon bridge wafers can include an array of probes having a nominal pitch, a space transformer configured to provide electrical connections from a plurality of terminals of the space transformer to the plurality of probes, wherein a second nominal pitch of the plurality of terminals is different than the nominal pitch of the probes, and a thermal device configured to adjust a nominal spacing of the array of probes using heat transfer.

In Example 2, the heat transfer device of Example 1 optionally is mounted to the space transformer.

In Example 3, the apparatus of any one or more of Examples 1-2 optionally includes one or more guide plates, wherein each probe of the array of probes is configured to pass through an opening of the one or more guide plates.

In Example 4, the thermal device of any one or more of Examples 1-3 optionally is configured to modulate a temperature of the one or more guide plates.

In Example 5, the apparatus of any one or more of Examples 1-4 optionally includes a first printed circuit board having wire bond connections to terminals of the space transformer.

In Example 6, the first printed circuit board of any one or more of Examples 1-5 optionally is physically mounted with the space transformer in addition to the wire bond connections.

In Example 7, the apparatus of any one or more of Examples 1-2 optionally includes a second printed circuit board configured to connect with test equipment, the first circuit board physically mounted to the second circuit board using electrical connections.

In Example 8, the nominal pitch of the probes of any one or more of Examples 1-7 optionally is 65 micrometers (um) or less at 25° C.

In Example 9, a method can include contacting a first plurality of terminals of a first circuit hoard with an array of probes of a test probe assembly, routing test signals of the first circuit board between the plurality of probes and test equipment using a space transformer coupled to the probes, electrically isolating the first circuit board from the array of probes, modulating a thermal device to change a nominal pitch of the array of test probes, contacting a second plurality of terminals of a second circuit board with the array of probes, and routing test signals of the second circuit board between the plurality of probes and the test equipment using the space transformer.

In Example 10, a nominal spacing of the first plurality of terminals and a nominal spacing of the second plurality of terminals of any one or more of Examples 1-9 optionally is different.

In Example 11, a nominal spacing of the first plurality of terminals and a nominal spacing of the second plurality of terminals of any one or more of Examples 1-10 optionally is 65 micrometers or less.

In Example 12, the first circuit board of any one or more of Examples 1-11 optionally is a first silicon bridge.

In Example 13, the second circuit board of any one or more of Examples 1-12 optionally is a second silicon bridge.

In Example 14, the modulating a thermal device of any one or more of Examples 1-13 optionally includes cooling the space transformer.

In Example 15, the modulating a thermal device of any one or more of Examples 1-14 optionally includes heating the space transformer.

In Example 16, the modulating a thermal device i of any one or more of Examples 1-15 optionally includes cooling a guide plate of the test probe assembly, wherein the plurality of probes pass through openings in the guide plate.

In Example 17, the modulating a thermal device of any one or more of Examples 1-16 optionally includes heating a guide plate of the test probe assembly, wherein the plurality of probes pass through openings in the guide plate.

Example 18 can include or use, or can optionally be combined with any portion or combination of any portions of any one or more of Examples 1 through 17 to include or use, subject matter that can include means for performing any one or more of the functions of Examples 1 through 17, or a machine-readable medium, such as a non-transitory machine readable medium, including instructions that, when performed by a machine, cause the machine to perform any one or more of the functions of Examples 1 through 17.

Each of these non-limiting examples can stand on its own, or can be combined with one or more of the other examples in any permutation or combination.

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the invention should be determined with reference to the appended claims, along with the full scope of equivalents to which such claims are legally entitled.

1. An apparatus for testing integrated circuit wafers, the apparatus comprising:
an array of probes having a nominal pitch;
a space transformer configured to provide electrical connections from a plurality of terminals of the space transformer to the array of probes, wherein a second nominal pitch of the plurality of terminals is different than the nominal pitch of the array of probes; and
a thermal device configured to adjust a nominal spacing of the array of probes using heat transfer.

2. The apparatus of claim 1, wherein the thermal device is mounted to the space transformer.

3. The apparatus of claim 1, including one or more guide plates, wherein each probe of the array of probes is configured to pass through an opening of the one or more guide plates.

4. The apparatus of claim 3, wherein the thermal device is configured to modulate a temperature of the one or more guide plates.

5. The apparatus of claim 1, including a first printed circuit board having wire bond connections to terminals of the space transformer.

6. The apparatus of claim 5, wherein the first printed circuit board is physically mounted with the space transformer in addition to the wire bond connections.

7. The apparatus of claim 5, including a second printed circuit board configured to connect with test equipment, the first circuit board physically mounted to the second circuit board using electrical connections.

8. The apparatus of claim 1, wherein the nominal pitch of the probes is 65 micrometers (μm) or less at 25° C.

9. The apparatus of claim 1, wherein the integrated circuit wafers are silicon bridge wafers.

10. A method comprising:
contacting a first plurality of terminals of a first circuit board with an array of probes of a test probe assembly;
routing test signals of the first circuit board between the array of probes and test equipment using a space transformer coupled to the array of probes;
electrically isolating the first circuit board from the array of probes;
modulating a thermal device to change a nominal pitch of the array of probes;
contacting a second plurality of terminals of a second circuit board with the array of probes; and
routing test signals of the second circuit board between the array of probes and the test equipment using the space transformer.

11. The method of claim 10, wherein a nominal spacing of the first plurality of terminals and a nominal spacing of the second plurality of terminals is different.

12. The method of claim 10, wherein a nominal spacing of the first plurality of terminals and a nominal spacing of the second plurality of terminals is 65 micrometers or less.

13. The method of claim 10, wherein the first circuit board is a first silicon bridge.

14. The method of claim 13, wherein the second circuit board is a second silicon bridge.

15. The method of claim 10, wherein the modulating a thermal device includes cooling the space transformer.

16. The method of claim 10, wherein the modulating a thermal device includes heating the space transformer.

17. The method of claim 10, wherein the modulating a thermal device includes cooling a guide plate of the test probe assembly, wherein the array of probes pass through openings in the guide plate.

18. The method of claim 10, wherein the modulating a thermal device includes heating a guide plate of the test probe assembly, wherein the array of probes pass through openings in the guide plate.
